(19) United States
(12) Patent Application Publication
(10) Pub. No.: US 2011/0057664 A1
(43) Pub. Date: Mar. 10, 2011

(54) DEVICE-DEPENDENT REPLACEABLE UNIT AND MANUFACTURING METHOD

(75) Inventor: Ken Miyata, Gunma (JP)

(73) Assignee: ADVANTEST CORPORATION, Tokyo (JP)

(21) Appl. No.: 12/851,276

(22) Filed: Aug. 5, 2010

Related U.S. Application Data
(63) Continuation of application No. PCT/JP2008/052060, filed on Feb. 7, 2008.

(51) Int. Cl. G01R 31/02

(52) U.S. Cl. 324/537

(57) ABSTRACT

There is provided a device-dependent replaceable unit for use with a test apparatus, which can reduce signal deterioration. The device-dependent replaceable unit is selected depending on a type of a device under test, and to be mounted on the test apparatus to form a signal path between the device under test and the test apparatus. The device-dependent replaceable unit includes a socket board that has a front surface and a back surface, where the device under test is to be moved close to or away from the front surface of the socket board, and a plurality of spring pins that are positioned in a same manner as a plurality of connection terminals of the device under test, where the spring pins are supported by the socket board in such a manner that upper ends of the spring pins protrude from the front surface of the socket board and come into contact with the connection terminals of the device under test.

### BACKGROUND

1. Technical Field

The present invention relates to a device-dependent replaceable unit and a manufacturing method. More specifically, the present invention relates to a device-dependent replaceable unit that is provided in a test apparatus for establishing electrical connection with a device under test and a manufacturing method for manufacturing the device-dependent replaceable unit.

2. Related Art

A semiconductor test apparatus is structured such that some of its components are replaceable, and can thus perform a variety of tests by changing the replaceable components. One of the replaceable components is a device-dependent replaceable unit that serves as an electrical interface between the test apparatus and a device under test.

The device-dependent replaceable unit is constituted by a device socket that is structured in accordance with the shape of the device under test and the arrangement of the connection terminals of the device under test, a connector that connects the device socket to the main body of the test apparatus, and the like. The test apparatus can deal with a variety of devices under test by changing the device-dependent replaceable unit through insertion and extraction of the connector.

Japanese Patent Application Publication No. 11-094896 discloses a socket board that is mounted on a performance board. The socket board has inter-layer interconnections, and electrically connects an IC socket that is mounted on its upper surface to a coaxial cable that is connected to its lower surface. The socket board also physically supports the IC socket.

Japanese Patent Application Publication No. 2000-235061 discloses a socket board that has a plurality of sockets mounted thereon. Similarly to the socket board disclosed in Patent Document 1, this socket board also physically supports the sockets, and is provided with socket interconnections to provide part of the electrical connection with the sockets.

Here, devices under test are required to process signals the speed of which increases on the every day basis. This accordingly increases the speed of the test signals produced by semiconductor test apparatuses, and the test signal speed has recently reached as high as the gigahertz range. Such high-frequency signals are susceptible to the distributed constant of the electrical interconnections, and suffer from enormous transmission loss, mismatch-induced reflection, stub-induced reflection and the like. The signal deterioration in the test apparatuses makes it difficult to accurately evaluate the devices under test. Therefore, there is a demand for effective measures.

### SUMMARY

Therefore, it is an object of an aspect of the innovations herein to provide a device-dependent replaceable unit and a manufacturing method, which are capable of overcoming the above drawbacks accompanying the related art. The above and other objects can be achieved by combinations described in the independent claims. The dependent claims define further advantageous and exemplary combinations of the innovations herein.

An aspect of the innovations herein may include a device-dependent replaceable unit that is selected depending on a type of a device under test. The device-dependent replaceable unit is to be mounted on a test apparatus to form a signal path between the device under test and the test apparatus. The device-dependent replaceable unit includes a socket board that has a front surface and a back surface, where the device under test is to be moved close to or away from the front surface of the socket board, and a plurality of spring pins that are positioned in a same manner as a plurality of connection terminals of the device under test, where the spring pins are supported by the socket board in such a manner that upper ends of the spring pins protrude from the front surface of the socket board and come into contact with the connection terminals of the device under test.

A different aspect of the innovations herein may include a device-dependent replaceable unit that is selected depending on a type of a device under test. The device-dependent replaceable unit is to be mounted on a test apparatus to form a signal path between the device under test and the test apparatus. The device-dependent replaceable unit includes a socket board that includes a plurality of vias penetrating therethrough, where the vias are positioned in a same manner as connection terminals on a back surface of a device socket that has on a front surface thereof connection terminals for the device under test, and the device socket is to be mounted on a front surface of the socket board, a block that is secured onto a back surface of the socket board, a spring pin that is embedded in the block in such a manner that an upper end of the spring pin protrudes from inside of the block to the back surface of the socket board and comes into contact with end surfaces of the vias at the back surface of the socket board, and a coaxial cable whose one end is connected to a lower end of the spring pin, where the coaxial cable extends from a back surface of the block toward the test apparatus.

A further different aspect of the innovations herein may include a device-dependent replaceable unit that is selected depending on a type of a device under test. The device-dependent replaceable unit is to be mounted on a test apparatus to form a signal path between the device under test and the test apparatus. The device-dependent replaceable unit includes a socket board that has a front surface to or from which the device under test is moved close or away, a connection member an upper end of which is, at the front surface of the socket board, electrically connected to a connection terminal of the device under test, a coaxial cable one end of which is connected to a lower end of the connection member, where the coaxial cable extends from a back surface of the socket board toward the test apparatus, and a conductor block that is secured onto the back surface of the socket board. Here, the conductor block is electrically coupled to a shield line of the coaxial cable and mechanically supports the coaxial cable.

A yet different aspect of the innovations herein may include a manufacturing method of manufacturing a device-dependent replaceable unit that is selected depending on a type of a device under test. The device-dependent replaceable unit is to be mounted on a test apparatus to form a signal path between the device under test and the test apparatus. The device-dependent replaceable unit includes a support that has a front surface and a back surface, a spring pin that is embedded in the support in such a manner that an upper end of the spring pin protrudes from inside of the support to the front surface of the support, and a coaxial cable one end of which is connected to a lower end of the spring pin, where the coaxial cable extends from the back surface of the support toward the test apparatus. Here, the manufacturing method includes inserting the spring pin into the support from the front surface, inserting the one end of the coaxial cable into the support from the back surface, and electrically coupling the spring pin and the coaxial cable to each other.

A different aspect of the innovations herein may include a test apparatus including a test head that performs a test on a device under test, and a device-dependent replaceable unit that is selected depending on a type of the device under test. The device-dependent replaceable unit is mounted on the test head to form a signal path between the device under test and the test apparatus. Here, the device-dependent replaceable unit includes a socket board that has a front surface and a back surface, where the device under test is to be moved close to or away from the front surface of the socket board, and a plurality of spring pins that are positioned in a same manner as a plurality of connection terminals of the device under test, where the spring pins are supported by the socket board in such a manner that upper ends of the spring pins protrude from the front surface of the socket board and come into contact with the connection terminals of the device under test.

A further different aspect of the innovations herein may include a test apparatus including a test head that performs a test on a device under test, and a device-dependent replaceable unit that is selected depending on a type of the device under test. The device-dependent replaceable unit is mounted on the test head to form a signal path between the device under test and the test apparatus. The device-dependent replaceable unit includes a socket board that includes a plurality of vias penetrating therethrough, where the vias are positioned in a same manner as connection terminals on a back surface of a device socket that has on a front surface thereof connection terminals for the device under test, and the device socket is to be mounted on a front surface of the socket board, a block that is secured onto a back surface of the socket board, a spring pin that is embedded in the block in such a manner that an upper end of the spring pin protrudes from inside of the block to the back surface of the socket board and comes into contact with end surfaces of the vias at the back surface of the socket board, and a coaxial cable one end of which is connected to a lower end of the spring pin, where the coaxial cable extends from a back surface of the block toward the test apparatus.

A yet different aspect of the innovations herein may include a test apparatus including a test head that performs a test on a device under test, and a device-dependent replaceable unit that is selected depending on a type of the device under test. The device-dependent replaceable unit is mounted on the test head to form a signal path between the device under test and the test apparatus. The device-dependent replaceable unit includes a socket board that has a front surface on which the device under test is to be mounted, a connection member an upper end of which is, at the front surface of the socket board, electrically connected to a connection terminal of the device under test, a coaxial cable one end of which is connected to a lower end of the connection member, where the coaxial cable extends from a back surface of the socket board toward the test apparatus, and a conductor block that is secured onto the back surface of the socket board. Here, the conductor block is electrically coupled to a shield line of the coaxial cable and mechanically supports the coaxial cable.

Here, all the necessary features of the present invention are not listed in the summary. The sub-combinations of the features may become the invention.

### BRIEF DESCRIPTION OF THE DRAWINGS

FIG. 1 schematically illustrates the entire structure of a test apparatus 100.

FIG. 2 is a vertical sectional view illustrating the configuration of a device-dependent replaceable unit 200.

FIG. 3 illustrates a bottom surface of a socket board 220.

FIG. 4 illustrates a connection structure 201 in the device-dependent replaceable unit 200.

FIG. 5 is a vertical sectional view illustrating the configuration of the device-dependent replaceable unit 200.

FIG. 6 illustrates the bottom surface of the socket board 220.

FIG. 7 illustrates an upper surface of a conductor block 240.

FIG. 8 is a horizontal sectional view illustrating a bottom surface of the conductor block 240.

FIG. 9 illustrates the connection structure 201 in the device-dependent replaceable unit 200.

### DESCRIPTION OF EXEMPLARY EMBODIMENTS

Hereinafter, an aspect of the present invention will be described based on some embodiments. The embodiments do not limit the invention according to the claims, and all the combinations of the features described in the embodiments are not necessarily essential to means provided by aspects of the invention.

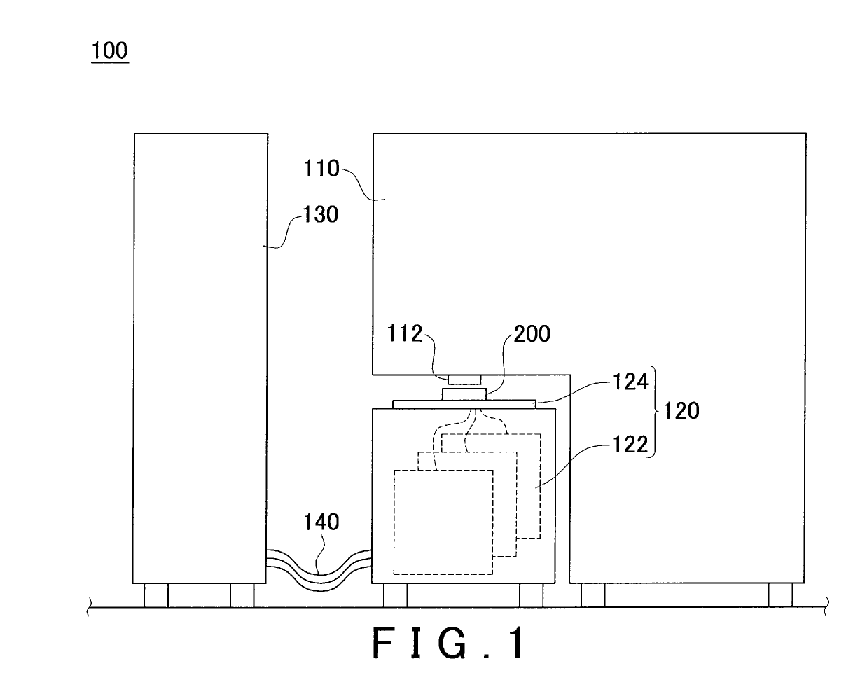

FIG. 1 schematically illustrates the entire structure of a test apparatus 100. The test apparatus 100 includes a handler 110, a test head 120, and a mainframe 130.

The handler 110 stores therein devices under test 112, and transports any required number of devices under test 112 each time requested to the test head 120 for tests. In this manner, a plurality of devices under test 112, for example, 512 memories under test, can be sequentially tested automatically.

The test head 120 houses therein a plurality of pin electronics circuits 122. A pin electronics circuit 122 generates a test signal to be sent to a device under test 112, in response to an instruction issued by the mainframe 130. The pin electronics circuit 122 sends the test signal to the device under test 112 and also receives the test signal that has been processed by the device under test 112 in order to evaluate the functions and characteristics of the device under test 112.

The pin electronics circuits 122 are connected to a motherboard 124.

On the upper surface of the test head 120, a device-dependent replaceable unit 200 is attached. Here, the attached device-dependent replaceable unit 200 is selected from among a plurality of different device-dependent replaceable units 200, and the connection portion of the attached device-dependent replaceable unit 200 needs to be shaped in the same manner as the connection portion of the device under test 112 that has been transported by the handler 110. The device-dependent replaceable unit 200 enables the device under test 112 to send/receive electrical signals to/from the test head 120.

The mainframe 130 is connected to the handler 110 and the test head 120 via connection cables 140 to comprehensively control the respective components.

When the test apparatus 100 including the above-described test head 120 is requested to test a different type of devices under test 112 or to perform a different type of tests, both or either of the device-dependent replaceable unit 200 and the pin electronics circuit 122 is changed. In this manner, the same test head 120 can continue to be used, and the expensive test apparatus 100 can be more efficiently used.

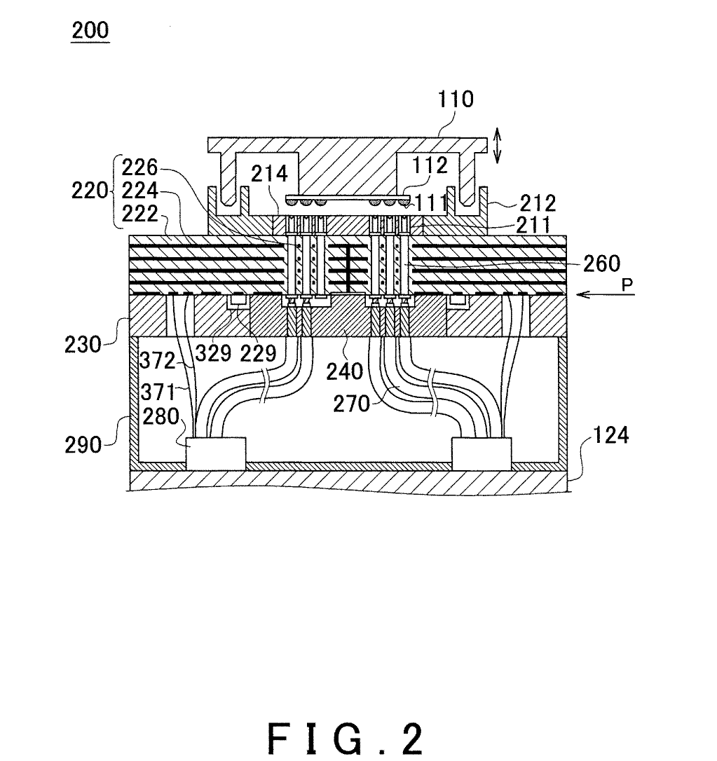

FIG. 2 is a vertical sectional view illustrating the configuration of the device-dependent replaceable unit 200. The device-dependent replaceable unit 200 is structured by sequentially layering a socket board 220, a spacer 230, a conductor block 240, and a housing 290.

The socket board 220 includes inter-layer interconnections 224 and inter-layer vias 226 that are integrated together within an insulation layer 222, and spring pins 260. Some of the inter-layer interconnections 224 are formed on the lower surface of the socket board 220. The inter-layer interconnections 224 are electrically connected to each other by means of the inter-layer vias 226.

On the upper surface of the socket board 220, a device socket 214 and a socket guide 212 are mounted. The device socket 214 has a plurality of through holes 211 that are positioned in the same manner as a plurality of connection terminals 111 of a device under test 112. The connection terminals 111 are, for example, formed in compatible with Ball Grid Array (BGA).

The device socket 214 also has members that guide the pins of the handler 110, which holds the device under test 112. Thus, the connection terminals 111 of the device under test 112 held by the handler 110 are positioned to oppose the through holes 211.

The spring pins 260 are embedded in the socket board 220 so as to penetrate the socket board 220 in the thickness direction. The spring pins 260 are guided and positioned in the same manner as the through holes 211 of the device socket 214.

The upper ends of the spring pins 260 protrude from the upper surface of the socket board 220, to extend into the through holes 211. In other words, the device socket 214 serves to house the spring pins 260 therein. Thus, when the device under test 112 is pressed by the handler 110, the connection terminals 111 come into contact with the upper ends of the spring pins 260.

The conductor block 240 is fastened to the lower surface of the socket board 220 in the region in which the spring pins 260 are arranged. The conductor block 240 is formed from a conductive material such as metal, and in contact with the inter-layer interconnections 224 formed on the lower surface of the socket board 220 to have the same potential as the inter-layer interconnections 224 formed on the lower surface of the socket board 220.

The spacer 230 surrounds the conductor block 240 to align the conductor block 240, and serves to flatten the lower surface of the assembly including the socket board 220, the conductor block 240, and the spacer 230. The spacer 230 is electrically conductive, and electrically connected to the inter-layer interconnections 224 formed on the bottom surface of the socket board 220. On the upper surface of the spacer 230, a depression 329 is provided to receive a capacitor 229 that is arranged on the lower surface of the socket board 220.

The housing 290 supports the above-described assembly from below, and houses therein connectors 280 and coaxial cables 270. The connectors 280 are attached to the bottom surface of the housing 290. When the device-dependent replaceable unit 200 is mounted onto the motherboard 124, the connectors 280 establish electrical connection with the circuits of the motherboard 124.

The coaxial cables 270 penetrate the conductor block 240, and electrically connect the lower ends of the spring pins 260 to the connectors 280. Furthermore, a power supply line 371 and a ground line 372 also electrically connect the inter-layer interconnections 224 to the connectors 280. Thus, when the device under test 112 is pressed by the handler 110, the connection terminals 111 are connected to the motherboard 124 via the spring pins 260, the coaxial cables 270, and the connectors 280.

Thus, there is provided the device-dependent replaceable unit 200 that is selected depending on the type of the device under test 112. The device-dependent replaceable unit 200 is to be mounted on the test apparatus 100 to form a signal path between the device under test 112 and the test apparatus 100. The device-dependent replaceable unit 200 includes the socket board 220 that has a front surface and a back surface, where the device under test 112 is to be moved by the handler 110 close to or away from the front surface of the socket board 220, and the plurality of spring pins 260 that are positioned in the same manner as the plurality of connection terminals 111 of the device under test 112, where the spring pins 260 are supported by the socket board 220 in such a manner that upper ends of the spring pins 260 protrude from the front surface of the socket board 220 and come into contact with the connection terminals 111 of the device under test 112. The device-dependent replaceable unit 200 further includes a socket guide 212 that guides the handler 110, which holds the device under test 112, so that the connection terminals 111 of the device under test 112 come into contact with the upper ends of the spring pins 260.

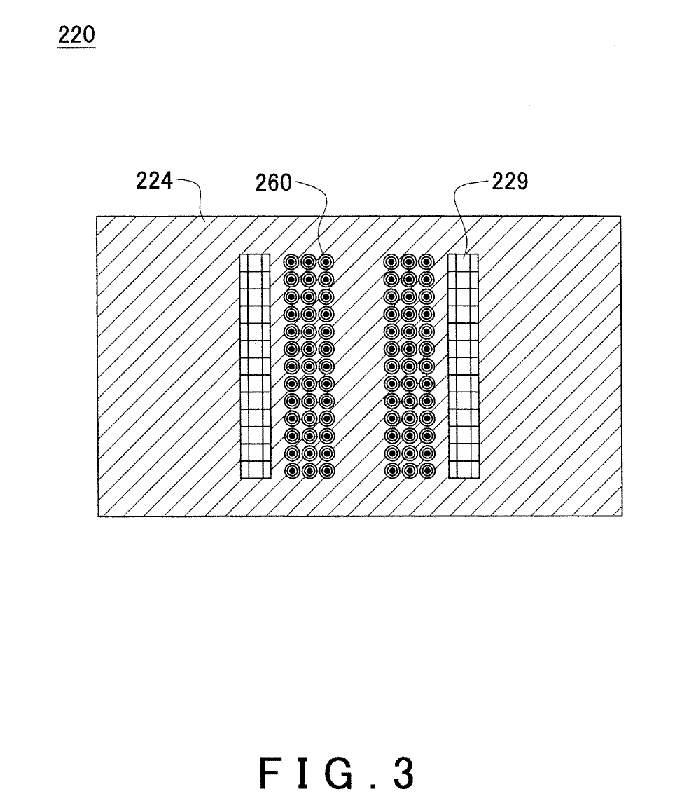

FIG. 3 illustrates the bottom surface of the socket board 220. The position of this bottom surface in the device-dependent replaceable unit 200 is indicated by the arrow Pin FIG. 2.

On the bottom surface of the socket board 220, some of the inter-layer interconnections 224 and the lower ends of the spring pins 260 are externally exposed. On the lower surface of the socket board 220, the capacitor 229 is also arranged.

The inter-layer interconnections 224 are formed on the entire bottom surface of the socket board 20, excluding the regions immediately adjacent to the spring pins 260. The lower ends of the spring pins 260 are spaced away from the inter-layer interconnections 224. Thus, when the spring pins 260 serve as signal paths, the spring pins 260 work together with the inter-layer interconnections 224 to form a distributed constant circuit at least within the plane containing the bottom surface of the socket board 220.

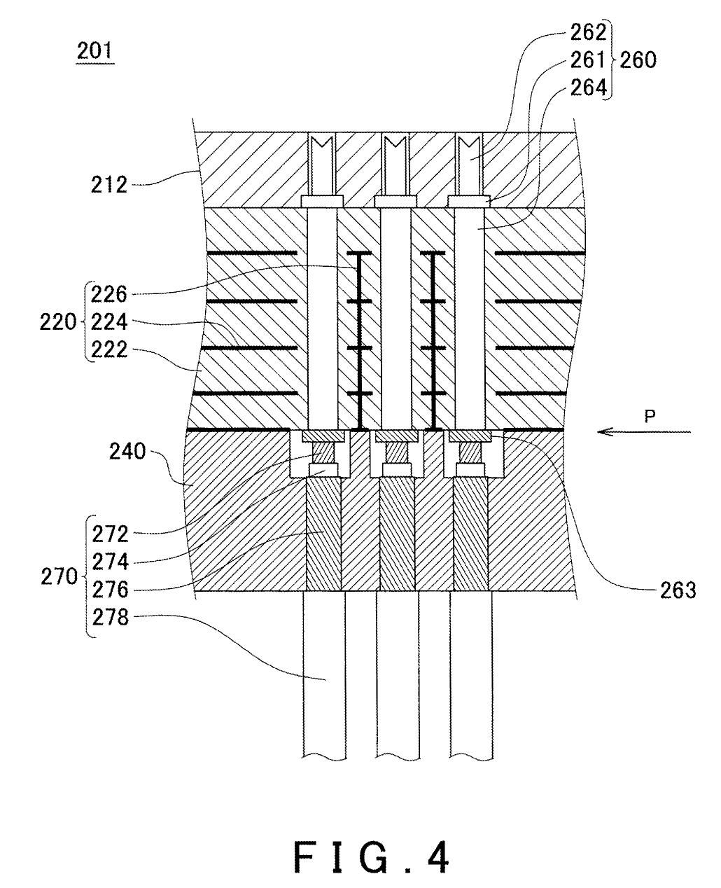

FIG. 4 illustrates a connection structure 201 forming the signal paths in the device-dependent replaceable unit 200. The signal paths from the device under test 112 mounted on the socket board 220 to the coaxial cables 270 are established by the spring pins 260.

Each spring pin 260 includes a sleeve 264 that is embedded in the socket board 220 so as to penetrate the socket board 220 in the thickness direction, and a contact pin 262 that extends from inside the sleeve 264 to above the socket board 220. The contact pin 262 can slide in the longitudinal direction within the sleeve 264 and is energized upwards by an energizing member provided in the sleeve 264. Thus, the contact pin 262 can absorb the height-direction dimensional errors of the device under test 112 and the connection terminals 111, and be reliably brought into contact with the connection terminals to establish electrical conduction therebetween.

The sleeve 264 of the spring pin 260 has an integrally-formed flange 261 at the upper end thereof. Thus, when the sleeve pin is inserted into a through hole formed in the socket board 220 so as to penetrate the socket board 220 in the thickness direction, the spring pin 260 does not go into the socket board 220 more than a certain depth. Furthermore, the flange 261 receives the reaction force that may occur when the connection terminals 111 come into contact with the upper ends of the contact pins 262, to contribute to form reliable electrical connection between the connection terminals 111 and the contact pins 262.

The flange 261 is pressed against the upper surface of the socket board 220 by the lower surface of the device socket 214. In this manner, the spring pin 260 is prevented from falling out from the socket board 220.

The lower end of the spring pin 260 slightly protrudes downward from the lower surface of the socket board 220, and is surrounded and fastened by a fastening member 263. The fastening member 263 is attached to the spring pin 260 immediately after the spring pin 260 is inserted into the socket board 220, and temporarily fastens the spring pin 260 until the device socket 214 is mounted on the socket board 220.

The socket board 220 has the inter-layer interconnections 224 that extend in parallel to the front and back surfaces of the socket board 220, and most of the inter-layer interconnections 224 are arranged within the socket board 220. The inter-layer interconnections 224 are arranged around the spring pins 260 penetrating the socket board 220, without contacting the spring pins 260. The inter-layer interconnections 224 are connected to each other by means of the inter-layer vias 226 that are embedded in the socket board 220 so as to extend in the thickness direction of the socket board 220.

The inter-layer interconnections 224 that are formed on the bottom surface of the socket board 220 are in contact with the conductor block 240. Thus, within the socket board 220, the spring pins 260 are each enclosed by a shield that is formed by the inter-layer interconnections 224 and the inter-layer vias 226 at the same potential as the conductor block 240, to form a coaxial transmission line.

The inter-layer interconnections 224 that are arranged within the socket board 220 and forms the shield do not need to be formed all over the socket board 220. In this case, some of the spring pins 260 may be used for supplying power or the like, and such spring pins 260 may be electrically connected to the inter-layer interconnections 224. In other words, some of the spring pins 260 and some of the inter-layer interconnections 224 may serve as low-speed signal lines that propagate low-speed signals such as power to be supplied to the device under test 112. In this case, the spring pins 260 that are electrically connected to the inter-layer interconnections 224 may not need to be connected at the bottom ends thereof to the coaxial cables.

Each coaxial cable 270 is constituted by a core line 272 that is positioned at the center in the radial direction of the coaxial cable 270, a shield line 276 that surrounds the core line 272 with a dielectric 274 therebetween, and an insulator 278 that externally surrounds the shield line 276. In the portion of the coaxial cable 270 adjacent to the upper end of the coaxial cable 270, the shield line 276 and the dielectrics 274 and 278 are removed so that the core line 272 is externally exposed. The exposed core line 272 is coupled to the lower end of the spring pin 260. Stated differently, the exposed core line 272 is pressed into the spring pin 260 through the lower end of the sleeve 264 of the spring pin 260, so that the coaxial cable 270 is electrically connected to the spring pin 260.

A portion of the coaxial cable 270 that is adjacent to the exposed core line 272 is inserted into the conductor block 240. This portion of the coaxial cable 270 does not have the outer insulator 278, so that the shield line 276 is in direct contact with the conductor block 240. Thus, the coaxial cable 270 is mechanically supported and secured by the conductor block 240, and the shield line 276 is at the same potential as the conductor block 240.

As already mentioned in the above, the conductor block 240 is connected to the inter-layer interconnections 224. Furthermore, the inter-layer interconnections 224 and the spring pins 260 together form coaxial structures. Accordingly, coaxial transmission lines extend from the coaxial cables 270 to the upper surface of the socket board 220.

Referring to the above-described connection structure 201, the portion of the coaxial cable 270 adjacent to the upper end decreases in outer diameter toward the upper end since more materials are removed. Therefore, when the respective components of the device-dependent replaceable unit 200 are assembled together, the coaxial cable 270 can be inserted into the assembly of the socket board 220 and the conductor block 240 from below.

Thus, a manufacturing method including inserting the spring pin 260 into the socket board 220 from the front surface, inserting the one end of the coaxial cable 270 into the socket board 220 from the back surface, and electrically coupling the spring pin 260 and the coaxial cable 270 to each other can manufacture the device-dependent replaceable unit 200 that is selected depending on the type of the device under test 112. The device-dependent replaceable unit 200 is to be mounted on the test apparatus 100 to form a signal path between the device under test 112 and the test apparatus 100. The device-dependent replaceable unit 200 includes the socket board 220 that has a front surface and a back surface, the spring pin 260 that is embedded in the socket board 220 in such a manner that the upper end of the spring pin 260 protrudes from inside of the socket board 220 to the front surface of the socket board 220, and the coaxial cable 270 one end of which is connected to the lower end of the spring pin 260, where the coaxial cable 270 extending from the back surface of the socket board 220 to the motherboard 124.

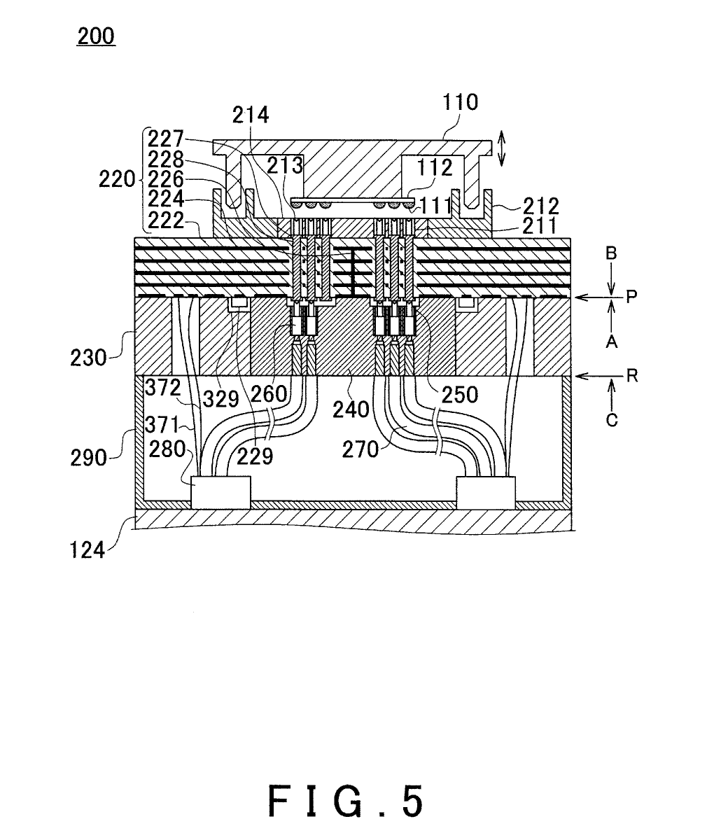

FIG. 5 is a vertical sectional view illustrating the configuration of a different embodiment of the device-dependent replaceable unit 200. The device-dependent replaceable unit 200 is structured by sequentially layering a socket board 220, a spacer 230, a conductor block 240, and a housing 290. Some of the constituents are shared between the present embodiment and the embodiment described with reference to FIGS. 1 to 4. Such constituents are designated by the same reference numbers and are not redundantly explained here.

The socket board 220 includes an insulation layer 222, inter-layer interconnections 224 and inter-layer vias 226, and through vias 228. On the upper surface of the socket board 220, a socket guide 212 and a device socket 214 are mounted.

The device socket 214 has therein a plurality of through holes 211 that are positioned in the same manner as connection terminals 111 of a device under test 112. In the through holes 211, connection members 213 are placed which have elasticity in the direction in which the through holes 211 extend. The connection members 213 are, for example, contact pins.

The socket guide 212 has members that guide the pins of the handler 110, which holds the device under test 112. Thus, the connection terminals 111 of the device under test 112 that is held by the handler 110 are brought into contact with the upper ends of the connection members 214 within the through holes 211.

Some of the inter-layer interconnections 224 are formed on the lower surface of the socket board 220. The inter-layer interconnections 224 are electrically connected to each other by means of the inter-layer vias 226.

The through vias 228 penetrate the socket board 220 in the thickness direction. At the respective ends of each through via 228, flat pads 227 are provided. The through vias 228 are electrically isolated from the inter-layer interconnections 224 and the inter-layer vias 226. On the upper surface of the socket board 220, the pads 227 are positioned in the same manner as the connection members of the device socket 210.

The conductor block 240 is secured to the lower surface of the socket board 220 in the region in which the through vias 228 are arranged. The conductor block 240 is formed from a conductive material such as metal, and has the same potential as the inter-layer interconnections 224 formed on the lower surface of the socket board 220 by contacting the inter-layer interconnections 224 formed on the lower surface of the socket board 220.

Spring pins 260 are embedded in the conductor block 240 and surrounded by dielectrics 250. The spring pins 260 are positioned in the same manner as the pads 227 arranged on the lower surface of the socket board 220. The upper ends of the spring pins 260 are in contact with the lower end surfaces of the through vias 228.

The spacer 230 surrounds the conductor block 240 to align the conductor block 240, and serves to flatten the lower surface of the assembly including the socket board 220, the conductor block 240, and the spacer 230.

The housing 290 supports the above-described assembly from below, and houses therein connectors 280 and coaxial cables 270. The connectors 280 are attached to the bottom surface of the housing 290. When the device-dependent replaceable unit 200 is mounted onto the motherboard 124, the connectors 280 establish electrical connection with the circuits of the motherboard 124.

The coaxial cables 270 are coupled to the lower ends of the spring pins 260 within the conductor block 240. Thus, the connection terminals 111 of the device under test 112, which is mounted on the device socket 210, are connected to the motherboard 124 through the connection members 214, the through vias 228, the spring pins 260, the coaxial cables 270 and the connectors 280.

Thus, there is provided the device-dependent replaceable unit 200 that is selected depending on the type of the device under test 112. The device-dependent replaceable unit 200 is to be mounted on the test apparatus 100 to form a signal path between the device under test 112 and the test apparatus 100. The device-dependent replaceable unit 200 includes the socket board 220 that includes the plurality of through vias 228 penetrating therethrough, where the through vias 228 are positioned in the same manner as the connection terminals on the back surface of the device socket 210 that has the connection members 214 for the device under test 112, and the device socket 210 is to be mounted on the front surface of the socket board 220, the conductor block 240 that is secured onto the back surface of the socket board 220, the spring pin 260 that is embedded in the conductor block 240 in such a manner that the upper end of the spring pin 260 protrudes from inside of the conductor block 240 to the back surface of the socket board 220 and comes into contact with the end surfaces of the through vias 228 at the back surface of the socket board 220, and the coaxial cable one end of which is connected to the lower end of the spring pin 260, where the coaxial cable extends from the back surface of the conductor block 240 toward the test apparatus.

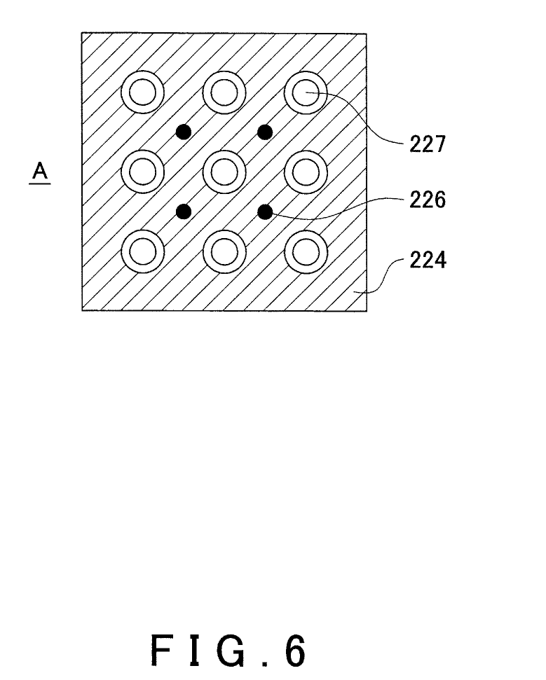

FIG. 6 illustrates the bottom surface of the socket board 220. The position of the bottom surface in the device-dependent replaceable unit 200 is indicated by the arrow P in FIG. 5. The arrow A in FIG. 5 indicates the direction in which the bottom surface is looked up.

On the bottom surface of the socket board 220, the undermost inter-layer interconnections 224, the pads 227 formed at the lower ends of the through vias 228, and the lower ends of the inter-layer vias 226 are seen. The inter-layer interconnections 224 are formed on the entire bottom surface of the socket board 220, excluding the regions immediately adjacent to the pads 227. The end surfaces of the inter-layer vias 226 are seen in the region in which the inter-layer interconnections 224 are formed.

The pads 227 formed on the lower ends of the through vias 228 are spaced away from the inter-layer interconnections 224. Thus, when the through vias 228 serve as signal paths, the pads 227 work together with the inter-layer interconnections 224 to form a distributed constant circuit at least within the plane containing the bottom surface of the socket board 220.

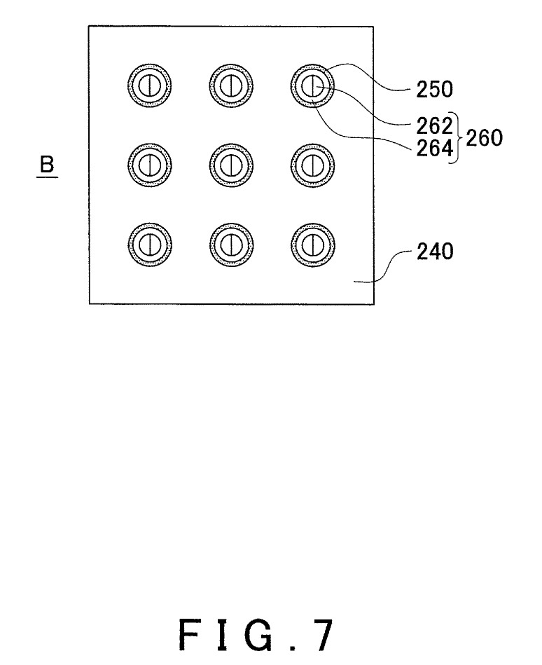

FIG. 7 illustrates the upper surface of the conductor block 240. The position of the upper surface is indicated by the arrow Pin FIG. 5. The arrow B in FIG. 5 indicates the direction in which the upper surface is looked down.

When the upper surface of the conductor block 240 is looked down, the spring pins 260 are seen which are embedded in the conductor block 240. Also, the dielectrics 250 are seen which are provided between the conductor block 240 and the spring pins 260. Thus, when the spring pins 260 serve as signal paths, the spring pins 260 work together with the conductor block 240 to form a distributed constant circuit at least within the plane containing the upper surface of the conductor block 240. The distributed constant is maintained over substantially the entire length of the spring pins 260.

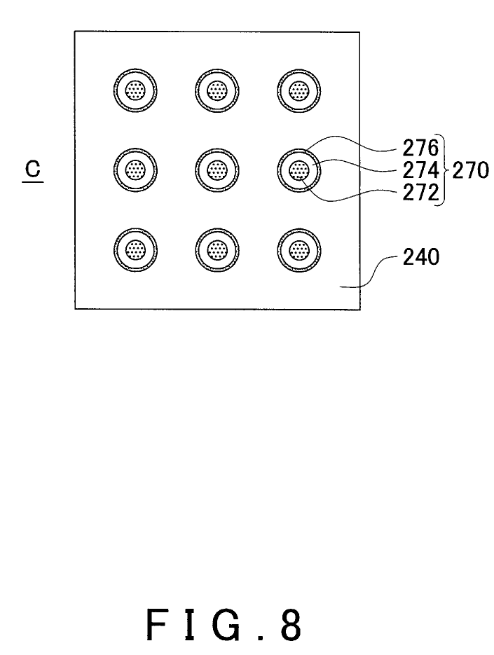

FIG. 8 is a horizontal sectional view illustrating the bottom surface of the conductor block 240. The position of the bottom surface in the device-dependent replaceable unit 200 is indicated by the arrow R in FIG. 5. The arrow C in FIG. 5 indicates the direction in which the bottom surface is looked up.

On the bottom surface of the conductor block 240, the transverse sectional surfaces of the coaxial cables 270, which are inserted into the conductor block 240, are seen. It is also seen that the outer insulators 278 are removed from the coaxial cables 270 and the shield lines 276 are thus in contact with the conductor block 240. This indicates that the shield lines 276 of the coaxial cables 270 are at the same potential as the conductor block 240. This state is always maintained as long as the shield lines 276 are in contact with the conductor block 240.

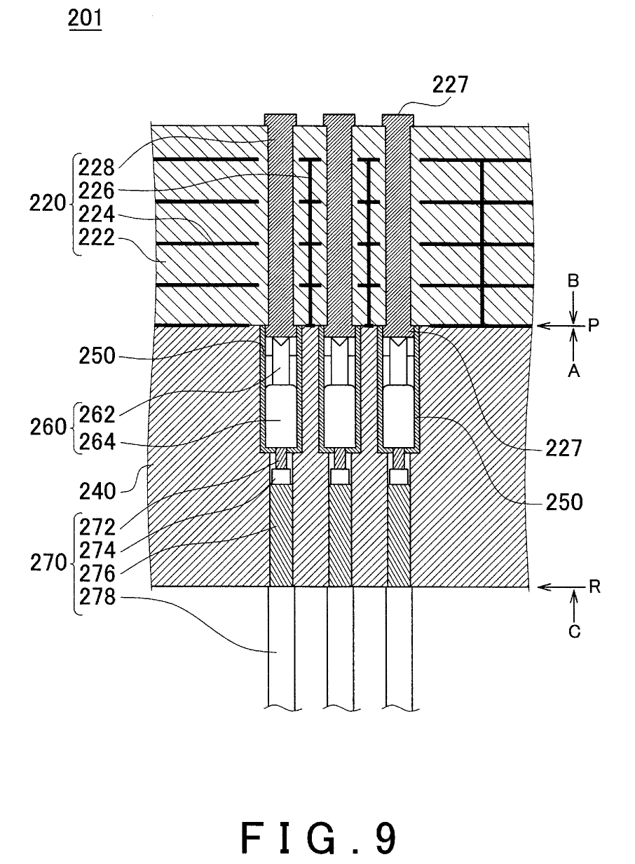

FIG. 9 illustrates an electrical connection structure 201 between the socket board 220 and the coaxial cables 270 in the device-dependent replaceable unit 200. Some of the constituents are shared between the present embodiment and different embodiments shown in different drawings, and such constituents are designated by the same reference numerals and not redundantly explained here.

The socket board 220 has the inter-layer interconnections 224 that are formed in parallel to the front and back surfaces of the socket board 220. The inter-layer interconnections 224 are connected to each other by means of the inter-layer vias 226 that extend in the thickness direction of the socket board 220. Note that, however, the inter-layer interconnections 224 are not in contact with through vias 228. Thus, within the socket board 220, the through vias 228 are each enclosed by a shield that is formed by the inter-layer interconnections 224 and the inter-layer vias 226, to form a coaxial transmission line.

The inter-layer interconnections 224 that are arranged within the socket board 220 and form the shield may not need to be formed all over the socket board 220. In this case, some of the through vias 228 may be used for supplying power or the like, and such through vias 228 may be electrically connected to the inter-layer interconnections 224. In other words, some of the through vias 228 and some of the inter-layer interconnections 224 may serve as low-speed signal lines that propagate low-speed signals such as power to be supplied to the device under test 112. In this case, the through vias 228 that are electrically connected to the inter-layer interconnections 224 may not need to be connected at the bottom ends thereof to the spring pins 260.

The inter-layer interconnections 224 that are formed on the bottom surface of the socket board 220 are in contact with the conductor block 240. The spring pins 260, which are embedded in the conductor block 240, are energized upwards so that the upper ends of the spring pins 260 are pressed against the pads 227. In this manner, electrical connection is established between the through vias 228 of the socket board 220 and the spring pins 260.

The dielectrics 250 are provided between the spring pins 260 and the conductor block 240, in which the spring pins 260 are embedded. The dielectrics 250 also cover the lower surfaces of the spring pins 260 and block electrical conduction between the spring pins 260 and the conductor block 240. Thus, the conductor block 240 and the spring pins 260 form coaxial structures. Since the dielectrics 250 are open at the upper ends, the spring pins 260 can be inserted from above.

In the portion of each coaxial cable 270 adjacent to the upper end of the coaxial cable 270, the shield line 276 and the dielectrics 274 and 278 are removed, so that the core line 272 is externally exposed. The exposed core line 272 is pressed into the spring pin 260 through the lower end of the sleeve 264 of the spring pin 260, so that electrical connection is established between the coaxial cable 270 and the spring pin 260.

A portion of the coaxial cable 270 that is adjacent to the exposed core line 272 is inserted into the conductor block 240. This portion of the coaxial cable 270 does not have the outer insulator 278, so that the shield line 276 is in direct contact with the conductor block 240. Thus, the coaxial cable 270 is mechanically supported and secured by the conductor block 240, and the shield line 276 is at the same potential as the conductor block 240 and the inter-layer interconnections 224. Thus, a coaxial transmission line is formed from the coaxial cable 270 to the upper surface of the socket board 220.

Referring to the above-described connection structure 201, the portion of the coaxial cable 270 adjacent to the upper end of the coaxial cable 270 decreases in outer diameter toward the upper end since more materials are removed. Therefore, when the respective components of the device-dependent replaceable unit 200 are assembled together, the coaxial cable 270 can be inserted into the conductor block 240 from below.

Thus, a manufacturing method including inserting the spring pin 260 into the conductor block 240 from the front surface, inserting the one end of the coaxial cable 270 into the conductor block 240 from the back surface, and electrically coupling the spring pin 260 and the coaxial cable 270 to each other can be used to manufacture the device-dependent replaceable unit 200 that is selected depending on the type of the device under test 112. The device-dependent replaceable unit is to be mounted on the test apparatus 100 to form a signal path between the device under test 112 and the test apparatus 100. The device-dependent replaceable unit includes the conductor block 240, the spring pin 260 that is embedded in the conductor block 240 in such a manner that the upper end of the spring pin 260 protrudes from inside of the conductor block 240 to the front surface of the conductor block 240, and the coaxial cable 270 one end of which is connected to the lower end of the spring pin 260, the coaxial cable 270 extending from the back surface of the conductor block 240 to the motherboard 124.

As described above, the signal path extending from the motherboard 124 to the device under test 112 largely has a coaxial structure due to the device-dependent replaceable unit 200. This can achieve impedance match in the signal path and reduce the attenuation of the transferred signal. In addition, unnecessary electromagnetic radiation and crosstalk caused by the transferred signal is suppressed. Therefore, the device-dependent replaceable unit 200 can be advantageously used, in particular, in a test apparatus for testing a high-frequency semiconductor device. When the connection terminals 111 of the device under test 112 are arranged at extremely small intervals and the coaxial cables 270 cannot be arranged at the same intervals as the connection terminals 111, each pair of adjacent lines may be combined to form a twin-lead balanced transmission line.

While an aspect of the present invention has been described based on some embodiments, the technical scope of the invention is not limited to the above described embodiments. It is apparent to persons skilled in the art that various alterations and improvements can be added to the above-described embodiments. It is also apparent from the scope of the claims that the embodiments added with such alternations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A device-dependent replaceable unit that is selected depending on a type of a device under test, the device-dependent replaceable unit to be mounted on a test apparatus to form a signal path between the device under test and the test apparatus, the device-dependent replaceable unit comprising:
a socket board that has a front surface and a back surface, the device under test to be moved close to or away from the front surface of the socket board; and
a plurality of spring pins that are positioned in a same manner as a plurality of connection terminals of the device under test, the spring pins being supported by the socket board in such a manner that upper ends of the spring pins protrude from the front surface of the socket board and come into contact with the connection terminals of the device under test.

2. The device-dependent replaceable unit as set forth in claim 1, wherein
the socket board further includes
a low-speed signal interconnection that transmits a low-speed signal to be supplied to the device under test.

3. The device-dependent replaceable unit as set forth in claim 1, wherein
lower ends of the spring pins protrude from the back surface of the socket board.

4. The device-dependent replaceable unit as set forth in claim 1, further comprising
a device socket that guides the device under test so that the connection terminals of the device under test come into contact with the upper ends of the spring pins.

5. The device-dependent replaceable unit as set forth in claim 4, wherein
the device socket presses the spring pins against the socket board.

6. The device-dependent replaceable unit as set forth in claim 1, wherein
lower ends of the spring pins are connected to first ends of coaxial cables that extend from the back surface of the socket board toward the test apparatus.

7. The device-dependent replaceable unit as set forth in claim 6, wherein
second ends of the coaxial cables are connected to a motherboard of the test apparatus.

8. The device-dependent replaceable unit as set forth in claim 6, wherein
the socket board includes a shield having:
a plurality of conductor layers that are formed in parallel to the front and back surfaces of the socket board; and
a via that is embedded in the socket board so as to extend in a thickness direction of the socket board, the via electrically coupling the conductor layers to each other.

9. The device-dependent replaceable unit as set forth in claim 8, further comprising
a conductor block that is secured onto the back surface of the socket board, the conductor block being electrically coupled to shield lines of the coaxial cables and mechanically supporting the coaxial cables.

10. The device-dependent replaceable unit as set forth in claim 9, wherein
the conductor block is electrically connected to the shield.

11. A device-dependent replaceable unit that is selected depending on a type of a device under test, the device-dependent replaceable unit to be mounted on a test apparatus to form a signal path between the device under test and the test apparatus, the device-dependent replaceable unit comprising:
a socket board that includes a plurality of vias penetrating therethrough, the vias being positioned in a same manner as connection terminals on a back surface of a device socket that has on a front surface thereof connection terminals for the device under test, the device socket to be mounted on a front surface of the socket board;
a block that is secured onto a back surface of the socket board;
a spring pin that is embedded in the block in such a manner that an upper end of the spring pin protrudes from inside of the block toward the back surface of the socket board and comes into contact with end surfaces of the vias at the back surface of the socket board; and
a coaxial cable one end of which is connected to a lower end of the spring pin, the coaxial cable extending from a back surface of the block toward the test apparatus.

12. The device-dependent replaceable unit as set forth in claim 11, wherein
the other end of the coaxial cable is connected to a motherboard of the test apparatus.

13. The device-dependent replaceable unit as set forth in claim 11, wherein
the socket board further includes
a low-speed signal interconnection that transmits a low-speed signal to be supplied to the device under test that is attached to the device socket.

14. The device-dependent replaceable unit as set forth in claim 11, wherein
the block is formed from a conductor, electrically coupled to a shield line of the coaxial cable, and mechanically supports the coaxial cable.

15. The device-dependent replaceable unit as set forth in claim 11, wherein
the socket board includes a shield having:
a plurality of conductor layers that are formed in parallel to the front and back surfaces of the socket board; and
a via that is embedded in the socket board so as to extend in a thickness direction of the socket board, the via electrically coupling the conductor layers to each other.

16. The device-dependent replaceable unit as set forth in claim 15, wherein
the block is electrically connected to the shield.

17. A device-dependent replaceable unit that is selected depending on a type of a device under test, the device-dependent replaceable unit to be mounted on a test apparatus to form a signal path between the device under test and the test apparatus, the device-dependent replaceable unit comprising:
a socket board that has a front surface which the device under test is moved close to or away from;
a connection member an upper end of which is, at the front surface of the socket board, electrically connected to a connection terminal of the device under test;
a coaxial cable one end of which is connected to a lower end of the connection member, the coaxial cable extending from a back surface of the socket board toward the test apparatus; and
a conductor block that is secured onto the back surface of the socket board, wherein
the conductor block is electrically coupled to a shield line of the coaxial cable and mechanically supports the coaxial cable.

18. The device-dependent replaceable unit as set forth in claim 17, wherein
the socket board includes a shield having:
a plurality of conductor layers that are formed in parallel to the front and back surfaces of the socket board; and
a via that is embedded in the socket board so as to extend in a thickness direction of the socket board, the via electrically coupling the conductor layers to each other, and
the conductor block is electrically connected to the shield.

19. A manufacturing method of manufacturing a device-dependent replaceable unit that is selected depending on a type of a device under test, the device-dependent replaceable unit to be mounted on a test apparatus to form a signal path between the device under test and the test apparatus, the device-dependent replaceable unit including:
a support that has a front surface and a back surface;
a spring pin that is embedded in the support in such a manner that an upper end of the spring pin protrudes from inside of the support toward the front surface of the support; and
a coaxial cable one end of which is connected to a lower end of the spring pin, the coaxial cable extending from the back surface of the support toward the test apparatus, wherein
the manufacturing method comprises:
inserting the spring pin into the support from the front surface;
inserting the one end of the coaxial cable into the support from the back surface; and
electrically coupling the spring pin and the coaxial cable to each other.

20. A test apparatus comprising:
a test head that performs a test on a device under test; and
a device-dependent replaceable unit that is selected depending on a type of the device under test, the device-dependent replaceable unit being mounted on the test head to form a signal path between the device under test and the test apparatus, wherein
the device-dependent replaceable unit includes:
a socket board that has a front surface and a back surface, the device under test to be moved close to or away from the front surface of the socket board; and
a plurality of spring pins that are positioned in a same manner as a plurality of connection terminals of the device under test, the spring pins being supported by the socket board in such a manner that upper ends of the spring pins protrude from the front surface of the socket board and come into contact with the connection terminals of the device under test.

21. A test apparatus comprising:
a test head that performs a test on a device under test; and
a device-dependent replaceable unit that is selected depending on a type of the device under test, the device-dependent replaceable unit being mounted on the test head to form a signal path between the device under test and the test apparatus, wherein
the device-dependent replaceable unit includes:
a socket board that has a plurality of vias penetrating therethrough, the vias being positioned in a same manner as connection terminals on a back surface of a device socket that has on a front surface thereof connection terminals for the device under test, the device socket to be mounted on a front surface of the socket board;
a block that is secured onto a back surface of the socket board;
a spring pin that is embedded in the block in such a manner that an upper end of the spring pin protrudes from inside of the block to the back surface of the socket board and comes into contact with end surfaces of the vias at the back surface of the socket board; and
a coaxial cable one end of which is connected to a lower end of the spring pin, the coaxial cable extending from a back surface of the block toward the test apparatus.

22. A test apparatus comprising:
a test head that performs a test on a device under test; and
a device-dependent replaceable unit that is selected depending on a type of the device under test, the device-dependent replaceable unit being mounted on the test head to form a signal path between the device under test and the test apparatus, wherein
the device-dependent replaceable unit includes:
a socket board that has a front surface on which the device under test is to be mounted;
a connection member an upper end of which is, at the front surface of the socket board, electrically connected to a connection terminal of the device under test;
a coaxial cable one end of which is connected to a lower end of the connection member, the coaxial cable extending from a back surface of the socket board toward the test apparatus; and
a conductor block that is secured onto the back surface of the socket board, and
the conductor block is electrically coupled to a shield line of the coaxial cable and mechanically supports the coaxial cable.
